(19) United States
(12) Patent Application Publication
(10) Pub. No.: US 2024/0250164 A1
(43) Pub. Date: Jul. 25, 2024

(54) DIODE, FIELD EFFECT TRANSISTOR HAVING THE DIODE, AND METHOD FOR MANUFACTURING THE DIODE

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventors: Masahiro KUMITA, Nisshin-shi (JP); Katsumi SUZUKI, Nisshin-shi (JP); Takuji ARAUCHI, Nisshin-shi (JP); Jun SAITO, Nisshin-shi (JP)

(21) Appl. No.: 18/543,719

(22) Filed: Dec. 18, 2023

(30) Foreign Application Priority Data
Jan. 20, 2023 (JP) 2023-007444

(51) Int. Cl. H01L 29/78; H01L 21/02; H01L 21/04; H01L 29/16; H01L 29/66

(52) U.S. Cl. CPC H01L 29/7805; H01L 21/02529; H01L 21/02576; H01L 21/0262; H01L 21/046; H01L 29/1608; H01L 29/66068; H01L 29/7813

(57) ABSTRACT

A diode has a semiconductor substrate made of silicon carbide. The semiconductor substrate includes a p-type first semiconductor region, a drift region below the first semiconductor region, and an n-type second semiconductor region below the drift region. The drift region has a plurality of p-type column regions and a plurality of n-type column regions alternately arranged in a lateral direction. The drift region includes a specific region distributed over the plurality of p-type column regions and the plurality of n-type column regions, at least at a part in a depth direction. The plurality of p-type column regions has an effective p-type impurity concentration that is lower in the specific region than in a portion around the specific region, and the plurality of n-type column regions has an effective n-type impurity concentration that is higher in the specific region than in a portion around the specific region.

### CROSS REFERENCE TO RELATED APPLICATION

The present application claims the benefit of priority from Japanese Patent Application No. 2023-007444 filed on Jan. 20, 2023. The entire disclosures of the above application are incorporated herein by reference.

### TECHNICAL FIELD

The present disclosure relates to a diode, a field effect transistor having the diode, and a method for manufacturing the diode.

### BACKGROUND

It has been known a metal oxide semiconductor field effect transistor (MOSFET) having a semiconductor substrate made of silicon carbide (SiC). For example, the semiconductor substrate includes a p-type base region, an n-type drift layer and a p-type deep layer, which are located below the base region, and an n-type substrate located below the drift layer and the deep layer. The drift layer and the deep layer are alternately arranged in a lateral direction. Such a MOSFET can maintain a high breakdown voltage by means of the drift layer and the deep layer.

### SUMMARY

The present disclosure describes a diode, a field effect transistor having the diode, and a method for manufacturing the diode. A diode according to an aspect of the present disclosure includes a semiconductor substrate made of silicon carbide. The semiconductor substrate includes a p-type first semiconductor region, a drift region below the first semiconductor region, and an n-type second semiconductor region below the drift region. The drift region has a plurality of p-type column regions and a plurality of n-type column regions alternately arranged in a lateral direction. The drift region includes a specific region distributed over the plurality of p-type column regions and the plurality of n-type column regions, at least at a part in a depth direction. The plurality of p-type column regions has an effective p-type impurity concentration that is lower in the specific region than in a region on a periphery of the specific region, and the plurality of n-type column regions has an effective n-type impurity concentration that is higher in the specific region than in a region on the periphery of the specific region.

### BRIEF DESCRIPTION OF THE DRAWINGS

Objects, features and advantages of the present disclosure will become more apparent from the following detailed description made with reference to the accompanying drawings, in which like parts are designated by like reference numbers and in which:

FIG. 1 is a cross-sectional view of a semiconductor device according to a first embodiment of the present disclosure;

FIG. 2 is a diagram for explaining a process for manufacturing the semiconductor device according to the first embodiment;

FIG. 3 is a schematic diagram of an apparatus for an epitaxial growth;

FIG. 4 is a diagram for explaining a process for manufacturing the semiconductor device according to the first embodiment;

FIG. 5 is a diagram for explaining a process for manufacturing the semiconductor device according to the first embodiment;

FIG. 6 is a diagram for explaining a process for manufacturing the semiconductor device according to the first embodiment;

FIG. 7 is a diagram for explaining a process for manufacturing the semiconductor device according to the first embodiment;

FIG. 8 is a graph showing the relationship between an introduction timing and an introduction amount of each gas as an example in a manufacturing method according to the first embodiment;

FIG. 9 is a graph showing a distribution of a nitrogen concentration in an upper n-type semiconductor layer manufactured by the manufacturing method according to the first embodiment;

FIG. 10 is a graph showing the relationship between the introduction timing and the introduction amount of each gas as another example in the manufacturing method according to the first embodiment;

FIG. 11 is a graph showing the relationship between the introduction timing and the introduction amount of each gas as a further another example in the manufacturing method according to the first embodiment; and

FIG. 12 is a cross-sectional view of a semiconductor device according to a second embodiment of the present disclosure.

### DETAILED DESCRIPTION

To begin with, a relevant technology will be described only for understanding the embodiments of the present disclosure.

In a metal-oxide-semiconductor field-effect transistor (MOSFET) having a semiconductor substrate made of silicon carbide (SiC), the semiconductor substrate may include a p-type base region, an n-type drift layer and a p-type deep layer, which are located below the base region, and an n-type substrate located below the drift layer and the deep layer. The drift layer and the deep layer may be alternately arranged in a lateral direction, and provide a high breakdown voltage in such a MOSFET.

The MOSFET may be formed with p-n diodes at an interface between the p-type base region and the n-type drift layer and at an interface between the p-type deep layer and the n-type substrate. When the diode is electrically conducted, holes flow from the base region toward the n-type substrate through the drift layer. Also, holes flow from the deep layer toward the n-type substrate. As a result, a large number of the holes are accumulated in the n-type substrate made of SiC.

It has been known that multiple basal plane dislocations exist inside SiC. The basal plane dislocation is a dislocation that is present on the (0001) plane (i.e., C plane), which is a basal plane of the SiC single crystal. When the hole concentration around the basal plane dislocation of the n-type substrate increases, a single Shockley stacking fault extends starting from the basal plane dislocation. An electric current hardly flows through the area where the stacking fault is formed. Namely, in the MOSFET described above, a large number of holes accumulated in the n-type substrate cause the stacking faults to extend over a wide range inside the n-type substrate. As a result, there is a problem that a current conductive region of the p-n diode is reduced. The present disclosure provides a technique for reducing the number of holes accumulated in an n-type semiconductor region and suppressing deterioration in electrical conduction in a diode having a semiconductor substrate made of SiC.

According to an aspect of the present disclosure, a diode includes a semiconductor substrate made of silicon carbide. The semiconductor substrate includes a p-type first semiconductor region, a drift region disposed in contact with a bottom portion of the first semiconductor region, and an n-type second semiconductor region disposed in contact with a bottom portion of the drift region. The drift region has a structure in which a plurality of p-type column regions and a plurality of n-type column regions are alternately arranged in a lateral direction. The drift region includes a specific region distributed over the plurality of p-type column regions and the plurality of n-type column regions, at least at a part in a depth direction. The plurality of p-type column regions has an effective p-type impurity concentration that is lower in the specific region than in a portion on a periphery of the specific region, and the plurality of n-type column regions has an effective n-type impurity concentration that is higher in the specific region than in a portion on a periphery of the specific region.

In the diode with the configuration described above, the semiconductor substrate includes the drift region having the structure in which the plurality of p-type column regions and the plurality of n-type column regions are alternately arranged in the lateral direction. The semiconductor substrate further includes the specific region provided at least in a part of the drift region in the depth direction and distributed over the p-type column regions and the n-type column regions of the drift region. The plurality of p-type column regions has the effective p-type impurity concentration that is lower in the specific region than in the portion on the periphery of the specific region, and the plurality of n-type column regions has the effective n-type impurity concentration that is higher in the specific region than in the portion on the periphery of the specific region. In the present disclosure, the effective p-type impurity concentration refers to a concentration obtained by subtracting the n-type impurity concentration from the p-type impurity concentration. Similarly, the effective n-type impurity concentration refers to a concentration obtained by subtracting the p-type impurity concentration from the n-type impurity concentration. That is, the hole concentration of the p-type column regions is lower in the specific region than in the portion on the periphery of the specific region, and the electron concentration of the n-type column regions is higher in the specific region than in the portion on the periphery of the specific region.

Since the effective n-type impurity concentration of the n-type column regions is relatively high in the specific region, some of the holes flowing into the second semiconductor region from the first semiconductor region via the n-type column regions are captured in the n-type column regions in the specific region. Since the n-type column regions have a higher electron concentration in the specific region than in the portion on the periphery of the specific region, the holes captured in the n-type column regions in the specific region are recombined with the electrons in the n-type column regions in the specific region and disappear. Further, since the effective p-type impurity concentration of the p-type column regions is relatively low in the specific region, some of the holes flowing into the second semiconductor region from the first semiconductor region via the p-type column regions are captured by the p-type column regions in the specific region. Since the p-type column regions have a lower hole concentration (that is, a higher relative electron concentration) in the specific region than in the portion on the periphery of the specific region, the holes captured by the p-type column regions in the specific region are recombined with electrons in the p-type column regions in the specific region and disappear.

As described above, in the diode, the number of holes reaching the second semiconductor region from the first semiconductor region via the drift region (i.e., via the p-type column regions and the n-type column regions) can be reduced. Therefore, the quantity of holes accumulated in the second semiconductor region made of SiC is reduced, and deterioration in electrical conduction can be suppressed.

According to an aspect of the present disclosure, a method for manufacturing a diode, which includes a p-type first semiconductor region made of silicon carbide, a drift region in contact with a bottom portion of the first semiconductor region and made of silicon carbide, and an n-type second semiconductor region in contact with a bottom portion of the drift region and made of silicon carbide, includes a process of forming the drift region. The forming of the drift region includes: forming a lower n-type semiconductor layer on the second semiconductor region by epitaxial growth; forming an upper n-type semiconductor layer on the lower n-type semiconductor layer by epitaxial growth; and forming a plurality of p-type column regions extending over the lower n-type semiconductor layer and the upper n-type semiconductor layer in a depth direction so that the lower n-type semiconductor region and the upper n-type semiconductor region remain between the plurality of p-type column regions as a plurality of n-type column regions, and the plurality of p-type column regions and the plurality of n-type column regions are alternately arranged in a lateral direction. The forming of the upper n-type semiconductor layer is performed under a condition that causes an n-type impurity concentration to be higher in a portion formed in an initial stage of the epitaxial growth than in a portion formed after the initial stage of the epitaxial growth.

In such a method, the forming of the upper n-type semiconductor layer is performed in the condition that causes the n-type impurity concentration of the upper n-type semiconductor layer to be higher in the portion formed in the initial stage of the epitaxial growth than in the portion formed after the initial state of the epitaxial growth. That is, the upper n-type semiconductor layer is formed such that the n-type impurity concentration of the portion formed in the vicinity of the upper surface of the lower n-type semiconductor layer is higher than the n-type impurity concentration of the portion of the upper n-type semiconductor layer formed thereafter. After this epitaxial growth, the plurality of p-type column regions are formed by the ion implantation to extend over the lower n-type semiconductor layer and the upper n-type semiconductor layer in the depth direction. A region at the bottom of the upper n-type semiconductor layer, that is, a specific region in the vicinity of the upper surface of the lower n-type semiconductor layer has a higher n-type impurity concentration than that in the other region. Therefore, the effective p-type impurity concentration of the p-type column regions inverted to the p-type by the ion implantation is lower in the specific region than in the other regions. Similarly, the effective n-type impurity concentration of the n-type column regions remaining after the ion implantation is higher in the specific region than in the other region. As a result, when the manufactured diode is electrically conducted, some of holes flowing from the first semiconductor region into the second semiconductor region via the drift region, such as the p-type column regions and the n-type column regions, are captured in the specific region. Therefore, in the diode manufactured by the method described above, the holes are less likely to be accumulated in the second semiconductor region at the time of the electrical conduction. Namely, it is possible to manufacture the diode in which deterioration in the electrical conduction is suppressed.

According to an aspect of the present disclosure, in the diode, the drift region may be formed with a plurality of the specific regions at intervals in the depth direction.

According to an aspect of the present disclosure, the diode may be included in a field effect transistor. The field effect transistor having the diode may include a plurality of trenches that penetrates the first semiconductor region from an upper surface of the semiconductor substrate and reaches the n-type column region, a gate insulating film covering an inner surface of each of the trenches, and a gate electrode disposed in each of the trenches and insulated from the semiconductor substrate through the gate insulating film. The semiconductor substrate may further include an n-type source region separated from the drift region through the first semiconductor region and in contact with the gate insulating film.

### First Embodiment

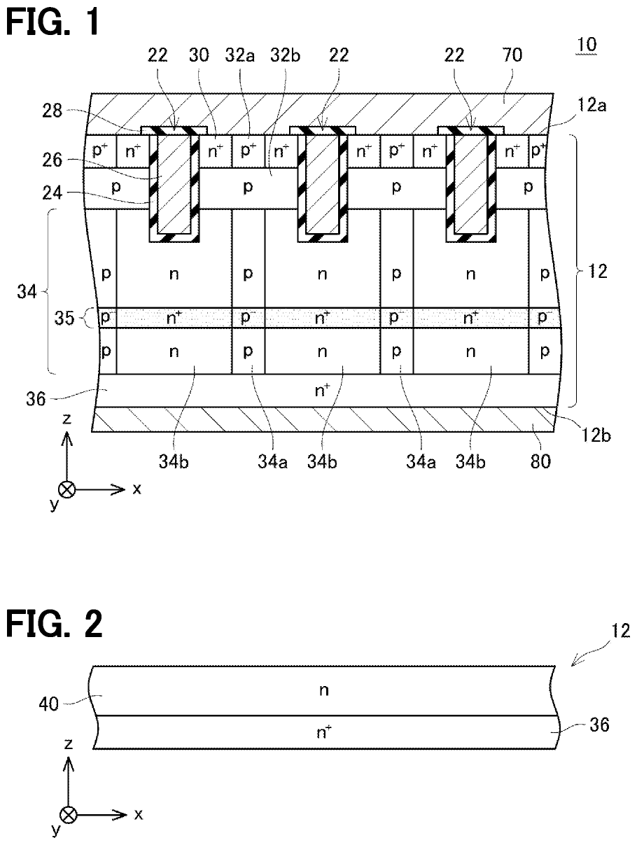

A semiconductor device 10 according to a first embodiment will be described with reference to the drawings. The semiconductor device 10 is a metal oxide semiconductor field effect transistor (MOSFET). As shown in FIG. 1, the semiconductor device 10 has a semiconductor substrate 12. The semiconductor substrate 12 is made of silicon carbide (SiC). A source electrode 70 is arranged at an upper surface 12a of the semiconductor substrate 12. A drain electrode 80 is arranged at a lower surface 12b of the semiconductor substrate 12. Hereinafter, a direction parallel to the upper surface 12a of the semiconductor substrate 12 is referred to as an x direction, and a direction parallel to the upper surface 12a of the semiconductor substrate 12 and orthogonal to the x direction is referred to as a y direction. Further, a thickness direction of the semiconductor substrate 12, which is orthogonal to the x direction and the y direction, is referred to as a z direction.

The semiconductor substrate 12 is formed with multiple trenches 22 in the upper surface 12a. As shown in FIG. 1, the multiple trenches 22 are arranged at intervals in the x direction. Each of the trenches 22 extends long in the y direction. A gate insulating film 24 and a gate electrode 26 are disposed in each of the trenches 22. The gate insulating film 24 is made of, for example, silicon oxide, and covers the inner surface of the trench 22. The gate electrode 26 is insulated from the semiconductor substrate 12 by the gate insulating film 24. An upper surface of the gate electrode 26 is covered with an interlayer insulating layer 28. The gate electrode 26 is insulated from the source electrode 70 by the interlayer insulating layer 28.

The semiconductor substrate 12 includes multiple source regions 30, a contact region 32a, a body region 32b, a drift region 34, and a drain region 36 therein. The source regions 30, the contact region 32a, the body region 32b, the drift region 34, and the drain region 36 are made of SiC.

Each of the source regions 30 is an n-type region. Each of the source regions 30 is exposed on the upper surface 12a of the semiconductor substrate 12. Each of the source regions 30 is in ohmic contact with the source electrode 70. Each of the source regions 30 is in contact with the gate insulating film 24 at the upper end portion of the corresponding trench 22.

The contact region 32a is a p-type region. The contact region 32a is arranged in a range interposed between the two source regions 30. The contact region 32a is exposed on the upper surface 12a of the semiconductor substrate 12. The contact region 32a is in ohmic contact with the source electrode 70.

The body region 32b is a p-type region. The body region 32b has a p-type impurity concentration lower than that of the contact region 32a. The body region 32b is disposed below the source region 30 and the contact region 32a, and is in contact with bottom portions of the source region 30 and the contact region 32a. The body region 32b is disposed below the source region 30, and is in contact with the gate insulating film 24 below the source region 30.

The drift region 34 is disposed below the body region 32b, and is in contact with a lower portion of the body region 32b. The drift region 34 includes multiple p-type column regions 34a and multiple n-type column regions 34b. The p-type column regions 34a and the n-type column regions 34b are alternately arranged along the x direction. Each of the p-type column regions 34a extends downward from a bottom end of the body region 32b. Each of the n-type column regions 34b is in contact with the gate insulating film 24 below the body region 32b. Each of the n-type column regions 34b is separated from the source region 30 by the body region 32b. A bottom end portion of each of the trenches 22 is surrounded by the corresponding n-type column region 34b.

The drift region 34 is provided with a specific region 35. The specific region 35 is provided in a part of the drift region 34 in the depth direction (z direction). The specific region 35 is distributed over the multiple p-type column regions 34a and the multiple n-type column regions 34b in the lateral direction. In the specific region 35, an effective p-type impurity concentration of the p-type column region 34a is lower than an effective p-type impurity concentration of the p-type column region 34a on a periphery thereof. That is, the effective p-type impurity concentration of the p-type column region 34a of the specific region 35 is lower than an effective p-type impurity concentration of the p-type column region 34a of the drift region 34 located above and below the specific region 35. In the specific region 35, an effective n-type impurity concentration of the n-type column region 34b is higher than an effective n-type impurity concentration of the n-type column region 34b on a periphery thereof. That is, the effective n-type impurity concentration of the n-type column region 34b of the specific region 35 is higher than the effective n-type impurity concentration of the n-type column region 34b of the drift region 34 located above and below the specific region 35.

The drain region 36 is an n-type region. The n-type impurity concentration of the drain region 36 is higher than the n-type impurity concentration of the n-type column region 34b. The drain region 36 is disposed below the drift region 34, and is in contact with a bottom portion of the drift region 34. The drain region 36 is exposed on the lower surface 12b of the semiconductor substrate 12. The drain region 36 is in ohmic contact with the drain electrode 80.

Next, an operation of the semiconductor device 10 will be described. In use of the semiconductor device 10, the drain electrode 80 is applied with a potential higher than that of the source electrode 70. When a potential equal to or higher than a gate threshold value is applied to the gate electrode 26, a channel is formed in the body region 32b in the vicinity of the gate insulating film 24. Thus, electrons flow from the source electrode 70 toward the drain electrode 80 via the source region 30, the channel in the body region 32b, the n-type column region 34b in the drift region 34, and the drain region 36. That is, the semiconductor device 10 is turned on. When the potential of the gate electrode 26 is lowered to a potential lower than the gate threshold value, the channel disappears and the flow of electrons stops. That is, the semiconductor device 10 is turned off.

In the semiconductor device 10, p-n diode is formed at the interface between the p-type body region 32b and the n-type column region 34b and at the interface between the p-type column region 34a and the n-type drain region 36. When the diode is energized, holes flow from the body region 32b toward the drain region 36 via the n-type column region 34b. Also, holes flow from the body region 32b toward the drain region 36 via the p-type column region 34a. Therefore, when the diode is turned on, a large number of holes are accumulated in the drain region 36 made of SiC.

As described above, since the basal plane dislocations exist in SiC, when the hole concentration around the basal plane dislocations in the drain region 36 increases, single Shockley stacking faults extend from the basal plane dislocations. In the area where the stacking faults are formed, it is extremely difficult for a current to flow, and deterioration in electrical conduction may occur. On the other hand, in the semiconductor device 10 of the present embodiment, the specific region 35 is provided in the drift region 34 in order to suppress the deterioration in electrical conduction. Since the effective n-type impurity concentration is relatively high in portions of the n-type column regions 34b in the specific region 35, some of the holes flowing from the body region 32b to the drain region 36 via the n-type column regions 34b are captured by the portions of the n-type column regions 34b in the specific region 35. In addition, since the portions of the n-type column regions 34b in the specific region 35 have a higher electron concentration than that in portions of the n-type column regions 34b on the periphery of the specific region 35, the holes captured in the portions of the n-type column region 34b in the specific region 35 are recombined with electrons in the portions of the n-type column region 34b in the specific region 35 and disappear. Further, since the effective p-type impurity concentration is relatively low in portions of the p-type column regions 34a in the specific region 35, some of the holes flowing from the body region 32b to the drain region 36 via the p-type column region 34a are captured by the portions of the p-type column regions 34a in the specific region 35. In addition, since the portions of the p-type column regions 34a in the specific region 35 have a lower hole concentration (that is, a higher relative electron concentration) than that in portions of the p-type column regions 34a on the periphery of the specific region 35, the holes captured in the portions of the p-type column regions 34a in the specific region 35 recombine with the electrons in the portions of the p-type column regions 34a in the specific region 35 and disappear.

As described above, in the semiconductor device 10 of the present embodiment, when the diode is turned on, the number of holes flowing from the body region 32b into the drain region 36 via the drift region 34 (that is, the p-type column regions 34a and the n-type column regions 34b) can be reduced. Therefore, the number of holes accumulated in the drain region 36 made of SiC is reduced, and the deterioration in the electrical conduction can be suppressed.

Next, a method for manufacturing the semiconductor device 10 will be described with reference to FIGS. 2 to 7. FIGS. 2 and FIGS. 4 through 7 show cross sections of the semiconductor device 10 corresponding to FIG. 1. First, a semiconductor substrate 12 made of a drain region 36 and before processing is prepared. Then, as shown in FIG. 2, a lower n-type semiconductor layer 40 is formed above the drain region 36 by epitaxial growth.

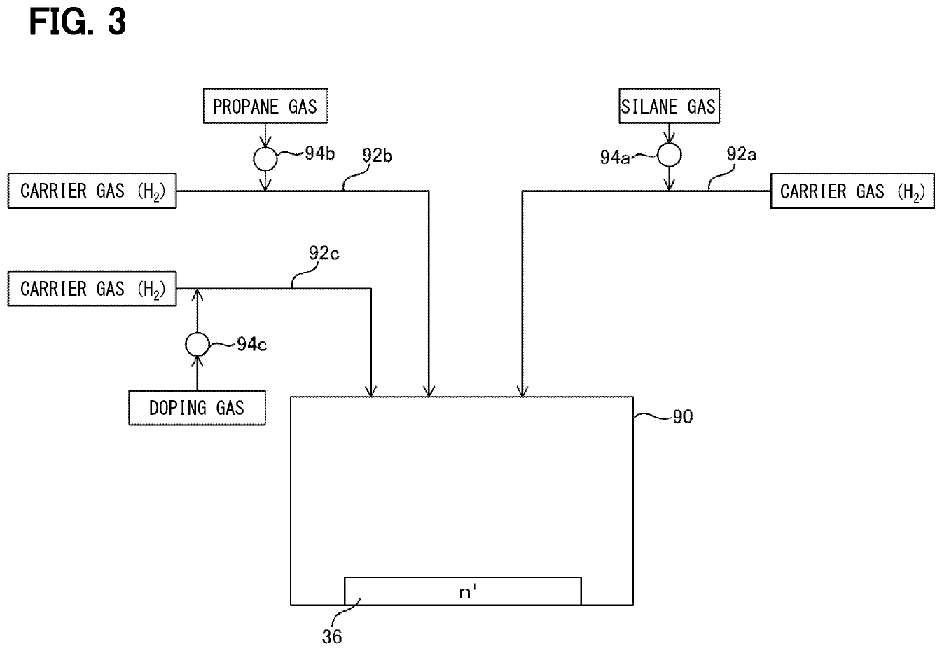

Specifically, as shown in FIG. 3, the semiconductor substrate 12 made of the drain region 36 is disposed in a chamber 90. The semiconductor substrate 12 is heated in the chamber 90. Into the chamber 90, monosilane gas (SiH₄), propane gas (C₃H₈), and doping gas (N₂) are supplied. As shown in FIG. 3, the monosilane gas is supplied into the chamber 90 together with a carrier gas (H₂) through a flow path 92a. The propane gas is supplied into the chamber 90 together with the carrier gas through a flow path 92b. The doping gas is supplied into the chamber 90 together with the carrier gas through a flow path 92c. The flow rate of the monosilane gas in the chamber 90 is controlled by a flow rate control valve 94a provided between a supply source of the monosilane gas and the flow path 92a. The flow rate of the propane gas in the chamber 90 is controlled by a flow rate control valve 94b provided between a supply source of the propane gas and the flow path 92b. The flow rate of the doping gas in the chamber 90 is controlled by a flow rate control valve 94c provided between a supply source of the doping gas and the flow path 92c.

In this case, the lower n-type semiconductor layer 40 is epitaxially grown on the drain region 36 by supplying the monosilane gas, the propane gas, and the doping gas into the chamber 90, as shown in FIG. 2.

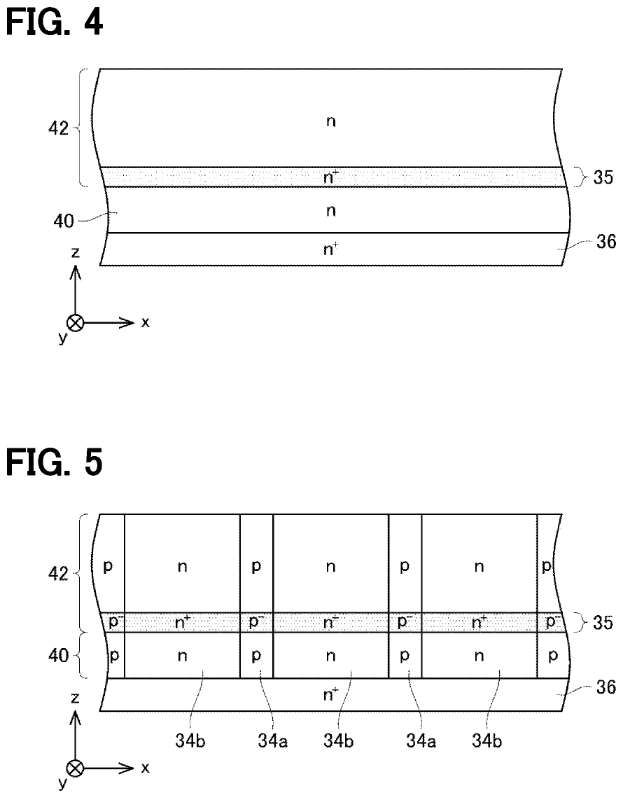

Next, as shown in FIG. 4, an upper n-type semiconductor layer 42 is formed above the lower n-type semiconductor layer 40 by epitaxial growth. This process is performed under conditions that cause the n-type impurity concentration to be locally increased in a portion of the upper n-type semiconductor layer 42 formed in an initial stage of the epitaxial growth. That is, the upper n-type semiconductor layer 42 is formed such that the n-type impurity concentration of the upper n-type semiconductor layer 42 formed in the vicinity of the upper surface of the lower n-type semiconductor layer 40 is higher than the n-type impurity concentration of the upper n-type semiconductor layer 42 formed thereafter. The lower n-type semiconductor layer 40 and the upper n-type semiconductor layer 42 constitute the drift region 34. In addition, the portion of the upper n-type semiconductor layer 42 formed in the initial stage in this process, that is, the portion of the upper n-type semiconductor layer 42 formed in the vicinity of the upper surface of the lower n-type semiconductor layer 40 serves as the specific region 35. The n-type impurity concentration of the specific region 35 is higher than the n-type impurity concentration of the portion of the upper n-type semiconductor layer 42 above the specific region 35 and the n-type impurity concentration of the lower n-type semiconductor layer 40. The condition, such as the supply timing and the supply amount of each gas, in the process of forming the upper n-type semiconductor layer 42 above the lower n-type semiconductor layer 40 will be described later.

Next, as shown in FIG. 5, multiple p-type column regions 34a are formed by ion-implantation of a p-type impurity into the lower n-type semiconductor layer 40 and the upper n-type semiconductor layer 42. In this case, the p-type impurity is ion-implanted so that the p-type impurity is distributed at a substantially uniform concentration from the upper surface of the upper n-type semiconductor layer 42 to the lower surface of the lower n-type semiconductor layer 40. The p-type impurity is selectively implanted at intervals. As a result, regions into which the p-type impurity is implanted are inverted to the p-type, and thus multiple p-type column regions 34a extending over the lower n-type semiconductor layer 40 and the upper n-type semiconductor layer 42 in the depth direction are formed. Further, the n-type region remaining between the p-type column regions 34a, that is, the region into which the p-type impurity is not implanted becomes the n-type column region 34b. As described in the process shown in FIG. 4, the specific region 35 having a higher n-type impurity concentration than the other regions has been formed at the bottom of the upper n-type semiconductor layer 42. Therefore, the effective p-type impurity concentration of the p-type column region 34a inverted to the p-type by the implantation of the p-type impurity is lower in the specific region 35 than in the other regions. Similarly, the effective n-type impurity concentration of the n-type column region 34b remaining after the implantation of the p-type impurity is higher in the specific region 35 than in the other regions.

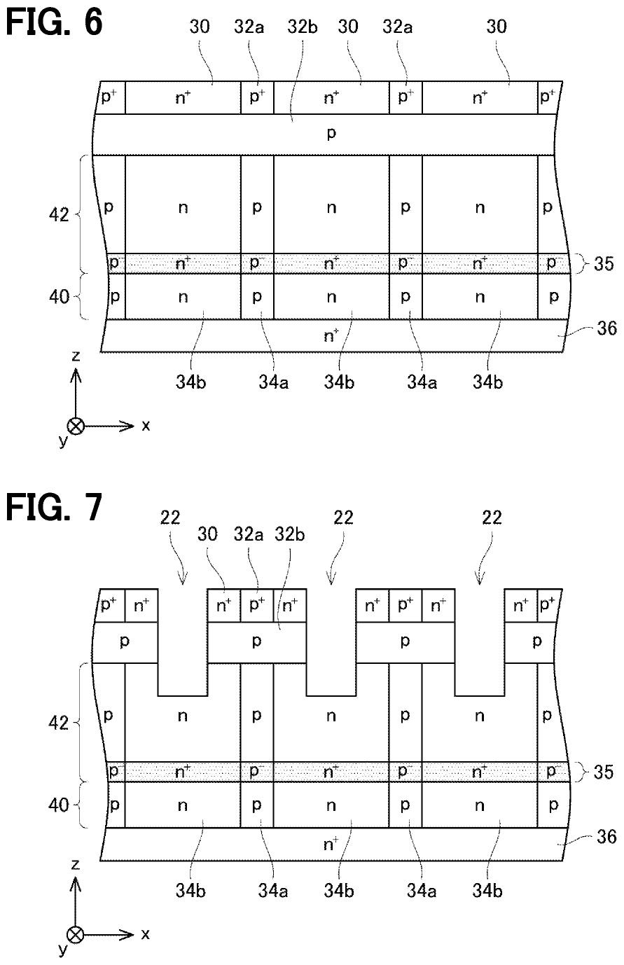

Next, as shown in FIG. 6, a p-type body region 32b, a source region 30, and a contact region 32a are formed above the upper n-type semiconductor layer 42 using epitaxial growth or ion implantation.

Next, as shown in FIG. 7, the upper surface 12a of the semiconductor substrate 12 is selectively etched so as to form multiple trenches 22. In this case, the trenches 22 each penetrating the source region 30 and the body region 32b and reaching the upper n-type semiconductor layer 42 are formed. Thereafter, an interlayer insulating layer 28, a gate insulating film 24, a gate electrode 26, a source electrode 70, and a drain electrode 80 are formed by using a technique such as chemical vapor deposition (CVD) or sputtering. In this way, the semiconductor device 10 shown in FIG. 1 is produced.

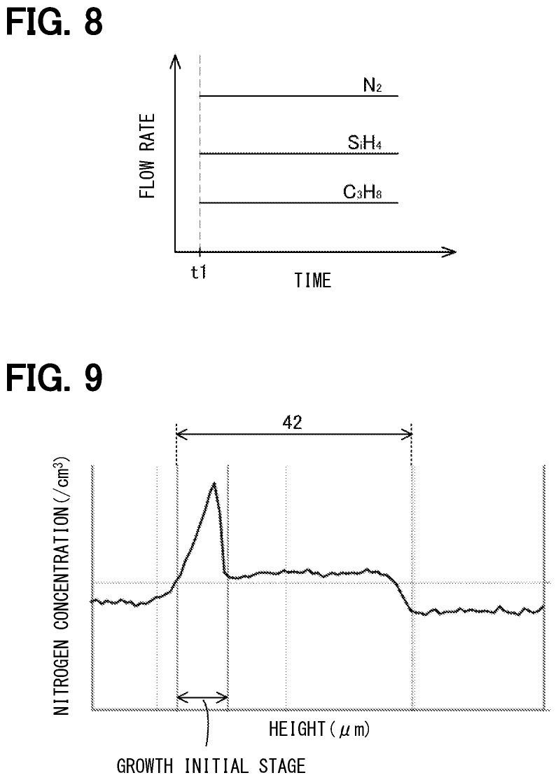

Next, the supply timing and the supply amount of each gas in the process of forming the upper n-type semiconductor layer 42 above the lower n-type semiconductor layer 40 by the epitaxial growth will be described with reference to FIGS. 8 to 11.

The propane gas and the monosilane gas supplied into the chamber 90 are decomposed in the chamber 90. As the propane gas is decomposed, a reactive carbon material (i.e., decomposed C atoms) is generated in the chamber 90. As the monosilane gas is decomposed, a reactive silicon material (i.e., decomposed Si atoms) is generated in the chamber 90. Hereinafter, the ratio of the reactive carbon material and the reactive silicon material present in the chamber 90 is referred to as a C/Si ratio. That is, the C/Si ratio is a value obtained by dividing the number of moles of the reactive carbon material by the number of moles of the reactive silicon material. The bonding energy of the monosilane gas is lower than the bonding energy of the propane gas. That is, the monosilane gas is more easily decomposed than the propane gas. Therefore, when the propane gas and the monosilane gas are supplied into the chamber 90 at a constant supply ratio, the C/Si ratio is low at the initial stage of the epitaxial growth, and is then increases as the time elapses.

The dopant concentration of the SiC layer (e.g., the upper n-type semiconductor layer 42) formed by the epitaxial growth depends on the C/Si ratio in the chamber 90. Specifically, nitrogen (N) as the n-type dopant is incorporated into SiC in a form coordinated with C. Therefore, the lower the C/Si ratio in the chamber 90 is, the easier the n-type dopant is incorporated into SiC. In other words, the smaller the amount of the reactive carbon material is in the gas, the easier the n-type dopant is incorporated into SiC. As such, the lower the C/Si ratio is, the higher the n-type dopant concentration in SiC formed by the epitaxial growth is.

In the manufacturing method of the present embodiment, by utilizing the above-described characteristics, the process of forming the upper n-type semiconductor layer 42 is performed under the condition that the n-type impurity concentration is locally increased in the portion of the upper n-type semiconductor layer 42 formed in the initial stage of the epitaxial growth.

Specifically, for example, as shown in FIG. 8, the monosilane gas and the propane gas are simultaneously introduced into the chamber 90 at time t1. As described above, since the monosilane gas is more easily decomposed than the propane gas, when the monosilane gas and the propane gas are simultaneously introduced into the chamber 90, the monosilane gas is decomposed prior to the propane gas. Therefore, in the initial stage of the epitaxial growth of the upper n-type semiconductor layer 42, a large amount of reactive silicon material is present, so that the C/Si ratio is low. Therefore, in the initial stage of growth of the upper n-type semiconductor layer 42, a portion having a high n-type impurity concentration is formed. Thereafter, when the ratio between the decomposition amount of propane gas and the decomposition amount of monosilane gas is stabilized and the C/Si ratio converges to a constant value, the n-type impurity concentration of the upper n-type semiconductor layer 42 is stabilized at a value lower than that in the initial growth stage.

In this way, by forming the upper n-type semiconductor layer 42 under the above-described conditions, as shown in the graph of FIG. 9, the n-type dopant concentration (i.e., the n-type impurity concentration) is locally increased in the portion of the upper n-type semiconductor layer 42 formed in the initial stage of the epitaxial growth (i.e., in a period in which the C/Si ratio is low). In a portion of the upper n-type semiconductor layer 42 formed in a later stage of the epitaxial growth (i.e., in a period in which the C/Si ratio is stable at a high value), the n-type impurity concentration is stable at a low value.

In the present embodiment, as described above, the portion having a higher n-type impurity concentration is formed in the upper n-type semiconductor layer 42 in the initial stage of the epitaxial growth. That is, the portion having a higher n-type impurity concentration is formed in the upper n-type semiconductor layer 42 in the vicinity of the upper surface of the lower n-type semiconductor layer 40. In this manner, the specific region 35 can be formed by adjusting the supply timing and the supply amount of each gas. As a result, it is possible to manufacture the semiconductor device 10 in which stacking faults are less likely to extend into the drain region 36 when the diode is electrically conducted, and deterioration in the electrical conduction is less likely to occur.

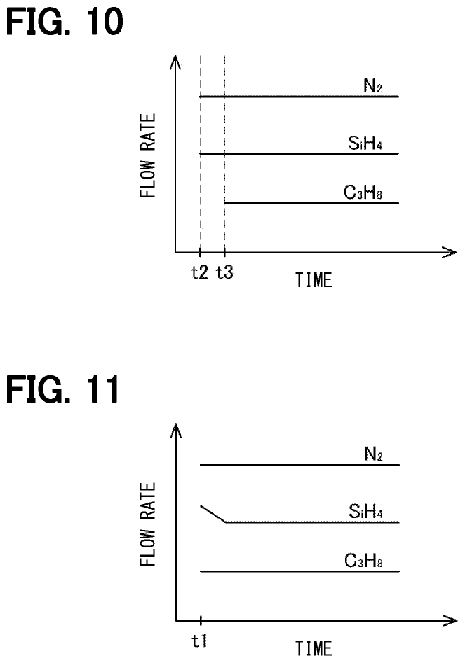

In the process of forming the upper n-type semiconductor layer 42, as another example shown in FIG. 10, after the introduction of monosilane gas into the chamber 90 is started at time t2, the propane gas may be introduced into the chamber 90 at time t3. As further another example, as shown in FIG. 11, in the configuration in which the monosilane gas and the propane gas are simultaneously introduced into the chamber 90 at time t1, the monosilane gas may be introduced into the chamber 90 such that the flow rate of the monosilane gas at the initial stage of growth of the upper n-type semiconductor layer 42 is higher than the flow rate thereafter. Even in these conditions, for the same reason as in the example shown in FIG. 8, the portion having the higher n-type impurity concentration (i.e., the specific region 35) can be formed in the initial stage of growth of the upper n-type semiconductor layer 42.

The p-n diode constituted by the body region 32b and the n-type column region 34b, and the p-type column region 34a and the drain region 36 is an example of the “diode”. The body region 32b and the drain region 36 are examples of a “first semiconductor region” and a “second semiconductor region”, respectively.

### Second Embodiment

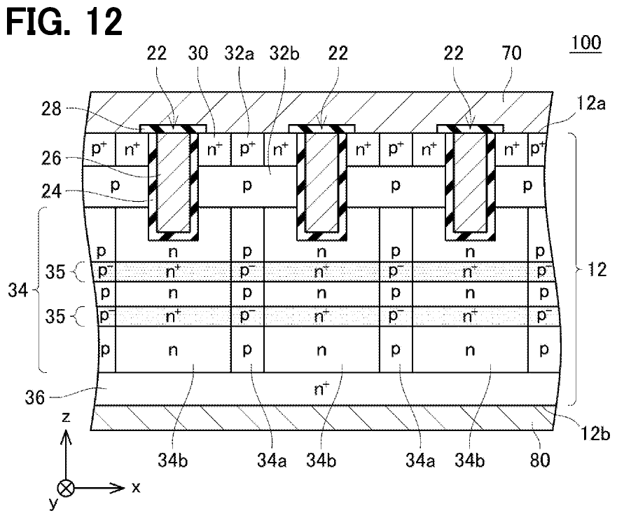

Next, a semiconductor device 100 according to a second embodiment will be described with reference to FIG. 12. In the semiconductor device 100 of the second embodiment, multiple specific regions 35 are provided in the drift region 34. As shown in FIG. 12, the specific regions 35 are arranged at intervals in the depth direction (i.e., in the z direction) of the semiconductor substrate 12. In such a configuration, the number of holes trapped in the specific region 35 is larger than that of the first embodiment. Therefore, the extension of the stacking faults in the drain region 36 is further suppressed, and the deterioration in the electrical conduction can be further suppressed.

In order to manufacture the semiconductor device 100 of the second embodiment, for example, after the process of forming the upper n-type semiconductor layer described with reference to the drawings of the first embodiment, an additional n-type semiconductor layer may be further formed above the upper n-type semiconductor layer under the same conditions as in the process of forming the upper n-type semiconductor layer. Thereafter, a p-type body region may be formed on the additional n-type semiconductor layer by the epitaxial growth.

In the embodiments described above, the p-type column region 34a may not be connected to the body region 32b in the cross-section shown in FIG. 1. The p-type column region 34a may have a potential substantially equal to that of the source electrode 70, and may be connected to the source electrode 70 via the body region 32b at a position not shown. The p-type column region 34a may not be connected to the drain region 36.

While only the selected exemplary embodiments and examples have been chosen to illustrate the present disclosure, it will be apparent to those skilled in the art from this disclosure that various changes and modifications can be made therein without departing from the scope of the disclosure as defined in the appended claims. Furthermore, the foregoing description of the exemplary embodiments and examples according to the present disclosure is provided for illustration only, and not for the purpose of limiting the disclosure as defined by the appended claims and their equivalents.

What is claimed is:

1. A diode comprising a semiconductor substrate made of silicon carbide,
the semiconductor substrate comprising:
a p-type first semiconductor region;
a drift region in contact with a bottom portion of the first semiconductor region; and
an n-type second semiconductor region in contact with a bottom portion of the drift region, wherein
the drift region has a structure in which a plurality of p-type column regions and a plurality of n-type column regions are alternately arranged in a lateral direction,
the drift region includes a specific region distributed over the plurality of p-type column regions and the plurality of n-type column regions in the lateral direction, at least at a part in a depth direction,
the plurality of p-type column regions has an effective p-type impurity concentration that is lower in the specific region than in a portion on a periphery of the specific region, and
the plurality of n-type column regions has an effective n-type impurity concentration that is higher in the specific region than in a portion on a periphery of the specific region.

2. The diode according to claim 1, wherein
the drift region includes a plurality of the specific regions arranged at intervals in the depth direction.

3. A field effect transistor comprising:
a diode that includes a semiconductor substrate made of silicon carbide, the semiconductor substrate including a p-type first semiconductor region, a drift region in contact with a bottom portion of the first semiconductor region, and an n-type second semiconductor region in contact with a bottom portion of the drift region;
a plurality of trenches penetrating the first semiconductor region from an upper surface of the semiconductor substrate and reaching the n-type column region;
a gate insulating film covering an inner surface of each of the plurality of trenches;
a gate electrode disposed in each of the plurality of trenches and insulated from the semiconductor substrate by the gate insulating film, wherein
in the diode,
the drift region has a structure in which a plurality of p-type column regions and a plurality of n-type column regions are alternately arranged in a lateral direction,
the drift region includes a specific region distributed over the plurality of p-type column regions and the plurality of n-type column regions in the lateral direction, at least at a part in a depth direction,
the plurality of p-type column regions has an effective p-type impurity concentration that is lower in the specific region than in a portion on a periphery of the specific region,
the plurality of n-type column regions has an effective n-type impurity concentration that is higher in the specific region than in a portion on a periphery of the specific region, and
the semiconductor substrate further includes an n-type source region that is separated from the drift region by the first semiconductor region and is in contact with the gate insulating film.

4. A method for manufacturing a diode, the diode including a p-type first semiconductor region made of silicon carbide, a drift region made of silicon carbide and being in contact with a bottom portion of the first semiconductor region, and an n-type second semiconductor region made of silicon carbide and being in contact with a bottom portion of the drift region,
the method for manufacturing the diode, comprising forming the drift region,
the forming of the drift region comprising:
forming a lower n-type semiconductor layer on the second semiconductor region by epitaxial growth;
forming an upper n-type semiconductor layer on the lower n-type semiconductor layer by the epitaxial growth; and
forming a plurality of p-type column regions by ion-implantation, the plurality of p-type column regions extending over the lower-n-type semiconductor layer and the upper-n-type semiconductor layer in a depth direction and being spaced apart from each other in a lateral direction so that the plurality of p-type column regions are alternately arranged with a plurality of n-type column regions in the lateral direction, the plurality of n-type column regions being provided by regions of the lower n-type semiconductor layer and the upper n-type semiconductor layer remaining between the plurality of p-type column regions, wherein
the forming of the upper n-type semiconductor layer is performed under a condition that causes a portion of the upper n-type semiconductor layer formed at an initial stage of the epitaxial growth to have an n-type impurity concentration higher than that of a portion of the upper n-type semiconductor layer formed after the initial stage.
